(19) United States
(12) Patent Application Publication
(10) Pub. No.: US 2025/0118702 A1
(43) Pub. Date: Apr. 10, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventor: Kwang Yong Lee, Suwon-si (KR)

(21) Appl. No.: 18/647,450

(22) Filed: Apr. 26, 2024

(30) Foreign Application Priority Data
Oct. 5, 2023 (KR) 10-2023-0132889
Nov. 9, 2023 (KR) 10-2023-0154435

(51) Int. Cl. H01L 23/00; H01L 23/31; H01L 25/065

(52) U.S. Cl. CPC H01L 24/80; H01L 24/08; H01L 23/3128; H01L 25/0657; H01L 2224/08145; H01L 2224/80365

(57) ABSTRACT

A semiconductor package may include a lower structure, and an upper structure on the lower structure. The lower structure may include a first semiconductor substrate, first pads on the first semiconductor substrate, and a first insulating layer enclosing the first pads. The upper structure includes a second semiconductor substrate, second pads on the second semiconductor substrate, and a second insulating layer enclosing the second pads. A side surface of the lower structure and a side surface of the upper structure form a stepwise structure near a bonding surface between the lower structure and the upper structure. The first insulating layer includes a protruding portion that extends to a level higher than a top surface of the first insulating layer and is inserted in the second insulating layer.

### CROSS-REFERENCE TO RELATED APPLICATIONS

This application claims priority to Korean Patent Application Nos. 10-2023-0132889 and 10-2023-0154435, filed in the Korean Intellectual Property Office on Oct. 5, 2023, and Nov. 9, 2023, respectively, the disclosure of which is incorporated by reference herein in its entirety.

### BACKGROUND

A semiconductor package includes a semiconductor chip that is provided as a part of an electronic product. In general, the semiconductor package includes a printed circuit board (PCB) and a semiconductor chip, which is mounted on the PCB and is electrically connected to the PCB using bonding wires or bumps. With the development of the electronic industry, various studies are being conducted to improve reliability and durability of the semiconductor package.

In the semiconductor industry, various package technologies have been developed to meet demands for large capacity, thin thickness, and small size of semiconductor devices and/or electronic products therewith. For example, a package technology of vertically stacking semiconductor chips has been suggested to realize a high-density chip stacking structure. This technology makes it possible to integrate semiconductor chips of various functions on a small area, compared with a typical package provided in the form of a single semiconductor chip.

### SUMMARY

In general, in some aspects, the present disclosure is directed toward a semiconductor package having improved structural stability and a method of fabricating the same.

In general, according to some aspects, the present disclosure is directed to a semiconductor package having a lower structure, and an upper structure on the lower structure. The lower structure may include a first semiconductor substrate, first pads on the first semiconductor substrate, and a first insulating layer provided on the first semiconductor substrate to enclose the first pads. The upper structure may include a second semiconductor substrate, second pads on the second semiconductor substrate, and a second insulating layer provided on the second semiconductor substrate to enclose the second pads. A side surface of the lower structure and a side surface of the upper structure may form a stepwise structure near a bonding surface between the lower structure and the upper structure. The first insulating layer may include a protruding portion, which is extended to a level higher than a top surface of the first insulating layer and is inserted in the second insulating layer. The protruding portion may be in contact with the side surface of the lower structure. Each of the first pads and a corresponding one of the second pads may be in direct contact with each other and may be formed of the same material to form a single object.

According to some aspects of the present disclosure, a semiconductor package may include a lower structure, and an upper structure on the lower structure. The lower structure may include a first semiconductor substrate, first pads on the first semiconductor substrate, and a first insulating layer provided on the first semiconductor substrate to enclose the first pads. The upper structure may include a second semiconductor substrate, second pads on the second semiconductor substrate, a second insulating layer provided on the second semiconductor substrate to enclose the second pads, and a slit structure vertically penetrating the second insulating layer. The first insulating layer may include a protruding portion, which is extended upward from a top surface of the first insulating layer and is inserted in the second insulating layer. A first side surface of the protruding portion may be exposed to an outside near a side surface of the lower structure. The slit structure may be exposed to an outside near a bottom surface of the second insulating layer and may be in contact with a top surface of the protruding portion. Each of the first pads and a corresponding one of the second pads may be in direct contact with each other and may be formed of the same material to form a single object.

According to some aspects of the present disclosure, a semiconductor package may include a substrate, a first semiconductor chip disposed on the substrate, a chip stack including second semiconductor chips, which are vertically stacked on the substrate and are horizontally spaced apart from the first semiconductor chip, and a mold layer provided on the substrate to enclose the first semiconductor chip and the chip stack. Each of the second semiconductor chips may include a semiconductor substrate, an upper pad disposed on a top surface of the semiconductor substrate, an upper insulating layer provided on the top surface of the semiconductor substrate to enclose the upper pad, a lower pad disposed on a bottom surface of the semiconductor substrate, and a lower insulating layer provided on the bottom surface of the semiconductor substrate to enclose the lower pad. The upper insulating layer may include a protruding portion which is extended upward from a top surface of the upper insulating layer. Adjacent ones of the second semiconductor chips may be in direct contact with each other. At contact surfaces between the second semiconductor chips, the lower pad and the upper pad may be in direct contact with each other and may be formed of the same material to form a single object. The protruding portion may be extended along an edge of the second semiconductor chip and may have a closed loop shape, when viewed in a plan view. A width of the protruding portion may range from 1 μm to 3 μm.

According to some aspects of the present disclosure, a method of fabricating a semiconductor package may include forming a lower structure including a first semiconductor substrate having device regions and a scribe lane region between the device regions, first pads disposed on the device regions of the first semiconductor substrate, and a first insulating layer disposed on the first semiconductor substrate to enclose the first pads, forming a protruding portion, which is extended upward from a top surface of the first insulating layer, on the first insulating layer on the scribe lane region, an upper structure including a second semiconductor substrate, second pads disposed on the second semiconductor substrate, and a second insulating layer disposed on the second semiconductor substrate to enclose the second pads, the first and second pads including the same metallic material, placing the upper structure on the lower structure to bring the first pads into contact with the second pads and insert the protruding portion into the second insulating layer, performing a thermal treatment process on the lower structure and the upper structure to form a single object, which is a result of bonding the first and second pads, and creating a crack in the scribe lane region of the first semiconductor substrate. The crack may propagate from the first semiconductor substrate to pass through the first insulating layer, the protruding portion, the second insulating layer, and the second semiconductor substrate.

### BRIEF DESCRIPTION OF THE DRAWINGS

FIG. 1 is a sectional view illustrating an example of a semiconductor package according to some implementations.

FIGS. 2 to 4 are enlarged views illustrating an example of a portion ‘A’ of FIG. 1 according to some implementations.

FIG. 5 is a plan view illustrating an example of a semiconductor package according to some implementations.

FIG. 6 is a sectional view illustrating an example of a semiconductor package according to some implementations.

FIG. 7 is an enlarged view illustrating an example of a portion ‘B’ of FIG. 6 according to some implementations.

FIG. 8 is a sectional view illustrating an example of a semiconductor package according to some implementations.

FIG. 9 is an enlarged view illustrating an example of a portion ‘C’ of FIG. 8 according to some implementations.

FIG. 10 is a sectional view illustrating an example of a semiconductor package according to some implementations.

FIG. 11 is an enlarged view illustrating an example of a portion ‘D’ of FIG. 10 according to some implementations.

FIG. 12 is a sectional view illustrating an example of a semiconductor package according to some implementations.

FIG. 13 is an enlarged view illustrating an example of a portion ‘E’ of FIG. 12 according to some implementations.

FIG. 14 is a sectional view illustrating an example of a semiconductor package according to some implementations.

FIG. 15 is an enlarged view illustrating an example of a portion ‘F’ of FIG. 14 according to some implementations.

FIG. 16 is a plan view illustrating an example of a semiconductor package according to some implementations.

FIG. 17 is an enlarged view illustrating an example of a portion ‘G’ of FIG. 16 according to some implementations.

FIG. 18 is a sectional view illustrating an example of a semiconductor package according to some implementations.

FIG. 19 is an enlarged view illustrating an example of a portion ‘H’ of FIG. 18 according to some implementations.

FIG. 20 is a sectional view illustrating an example of a semiconductor package according to some implementations.

FIG. 21 is an enlarged view illustrating an example of a portion ‘I’ of FIG. 20 according to some implementations.

FIG. 22 is a sectional view illustrating an example of a semiconductor package according to some implementations.

FIG. 23 is an enlarged view illustrating an example of a portion of FIG. 22 according to some implementations.

FIG. 24 is a sectional view illustrating an example of a semiconductor module according to some implementations.

FIGS. 25 to 39 are sectional views illustrating an example of a method of fabricating a semiconductor package according to some implementations.

### DETAILED DESCRIPTION

Hereinafter, example implementations will be explained in detail with reference to the accompanying drawings.

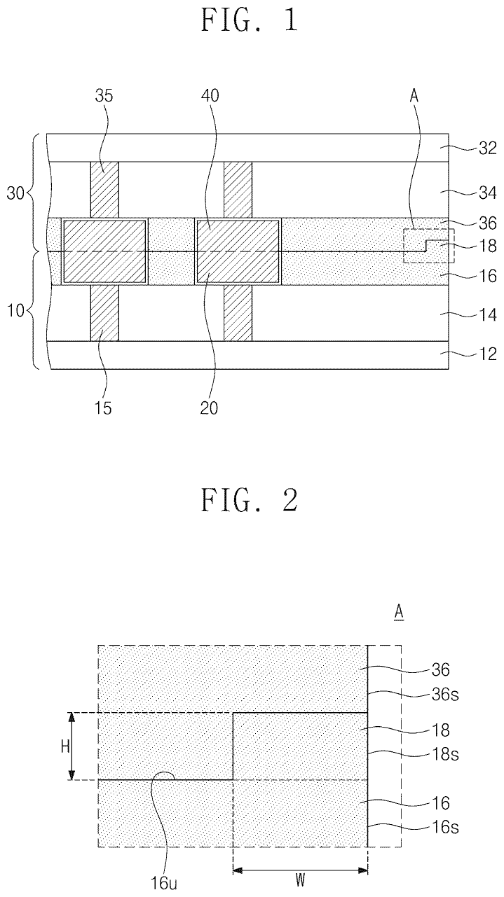

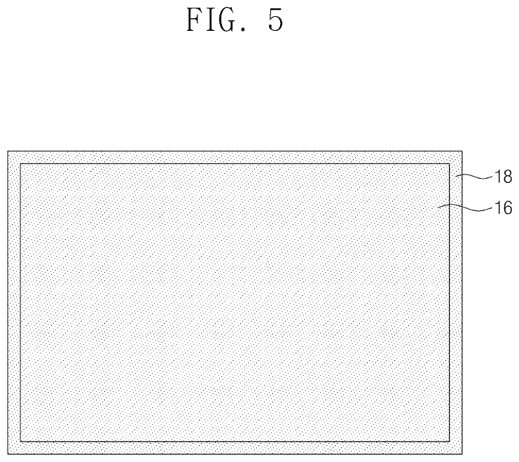

FIG. 1 is a sectional view illustrating an example of a semiconductor package according to some implementations. FIGS. 2 to 4 are enlarged views illustrating an example of a portion ‘A’ of FIG. 1 according to some implementations. FIG. 5 is a plan view illustrating an example of a semiconductor package according to some implementations.

In FIG. 1, a semiconductor device may include a lower structure 10 and an upper structure 30 stacked on the lower structure 10. The lower structure 10 may include a first substrate 12, a first circuit layer 14, a first insulating layer 16, and first pads 20.

The first substrate 12 may be a semiconductor substrate (e.g., a semiconductor wafer). The first substrate 12 may be a bulk silicon substrate, a silicon-on-insulator (SOI) substrate, a germanium substrate, a germanium-on-insulator (GOI) substrate, a silicon-germanium substrate, or a substrate including an epitaxial layer grown using a selective epitaxial growth (SEG) technique. The first substrate 12 may be formed of or include at least one of silicon (Si), germanium (Ge), silicon germanium (SiGe), gallium arsenic (GaAs), indium gallium arsenic (InGaAs), or aluminum gallium arsenic (AlGaAs). Alternatively, the first substrate 12 may be an insulating substrate (e.g., a printed circuit board (PCB)).

The first circuit layer 14 may be disposed on a top surface of the first substrate 12. The first circuit layer 14 may include a first circuit pattern provided on the first substrate 12 and a first interlayer insulating layer covering the first circuit pattern. The first circuit pattern may be a memory circuit with one or more transistors, a logic circuit with one or more transistors, or combinations thereof. Alternatively, the first circuit pattern may include at least one of passive devices (e.g., resistors, inductors, or capacitors).

The first pads 20 may be disposed on a top surface of the first circuit layer 14. The first pads 20 may be electrically connected to the first circuit pattern of the first circuit layer 14. The first pads 20 may have substantially the same thickness. For example, the first pad 20 may have a plate-shaped structure. In some implementations, the first pad 20 may include a via portion and a pad portion, which is provided on and connected to the via portion. Here, the via and pad portions of the first pad 20 may have a T-shaped section and may form a single object. A width of the first pad 20 may be substantially constant, regardless of a distance from the first substrate 12. Alternatively, the width of the first pad 20 may decrease as a distance to the first substrate 12 decreases, unlike the structure illustrated in FIG. 1. The first pads 20 may be arranged in a rectangular shape or in a honeycomb shape. However, the first pads 20 are not limited to this example. The planar shape of the first pad 20 may be circular. Alternatively, the planar shape of the first pad 20 may be tetragonal, octagonal, or polygonal. However, the inventive concept is not limited to these examples, and in an embodiment, the planar shape of the first pads 20 may be variously changed, if necessary. The first pads 20 may include a metallic material. For example, the first pads 20 may be formed of or include copper (Cu).

The first pads 20 may be electrically connected to the first circuit pattern of the first circuit layer 14. For example, a first connection pattern 15 may be provided in the first circuit layer 14, as shown in FIG. 1. The first connection pattern 15 may be a penetration via (e.g., a through-silicon via) that is provided to vertically penetrate the first interlayer insulating layer in the first circuit layer 14. The first connection pattern 15 may be vertically extended in the first circuit layer 14 and may be coupled to the first pad 20. The first connection pattern 15 may electrically connect the first circuit pattern to the first pad 20. In FIG. 1, various conductive patterns may be further provided for the interconnection between the first circuit pattern and the first connection pattern 15. The first connection pattern 15 may be an under-pad pattern or a redistribution pattern, which is provided in an insulating pattern in the first circuit layer 14, unlike the structure illustrated in FIG. 1. Various conductive patterns may be further provided for the interconnection between the first circuit pattern and the first connection pattern 15. However, the conductive patterns are not limited to this example, and if necessary, the shape of the first circuit layer 14 may be variously changed and the electrical interconnection between the first pads 20 and the first circuit layer 14 may be achieved by other various structures.

The first pads 20 may have a damascene structure, in the first insulating layer 16. For example, the first pads 20 may further include seed/barrier patterns covering side and bottom surfaces of the first pads 20. The seed/barrier patterns may conformally cover the side and bottom surfaces of the first pads 20. Where the seed/barrier patterns are used as a seed pattern, the seed/barrier patterns may include a metallic material (e.g., gold (Au)). Where the seed/barrier patterns are used as a barrier pattern, the seed/barrier patterns may be formed of or include at least one of metallic materials (e.g., titanium (Ti) and tantalum (Ta)) or metal nitride materials (e.g., titanium nitride (TiN) and tantalum nitride (TaN)).

The first insulating layer 16 may be provided on the top surface of the first circuit layer 14 to enclose the first pads 20. Top surfaces of the first pads 20 may be exposed to the outside of the first insulating layer 16. For example, the first insulating layer 16 may enclose the first pads 20 and may not cover the first pads 20, when viewed in a plan view. A top surface of the first insulating layer 16 and the top surfaces of the first pads 20 may be substantially flat and may be substantially coplanar with each other. The first insulating layer 16 may include an oxide, nitride, or oxynitride material containing an element included in the first substrate 12 or the first circuit layer 14. The first insulating layer 16 may include at least one of insulating materials (e.g., silicon oxide (SiO), silicon nitride (SiN), silicon oxynitride (SiON), or silicon carbon nitride (SiCN)). In some implementations, the first insulating layer 16 may be formed of or include silicon oxide (SiO).

The first insulating layer 16 may include a protruding portion 18. The protruding portion 18 may be placed at a level higher than a top surface 16u of the first insulating layer 16. The protruding portion 18 may be disposed near a side surface 16s of the first insulating layer 16. As an example, the protruding portion 18 may be in contact with the side surface 16s of the first insulating layer 16 (i.e., the side surface of the lower structure 10). Accordingly, a side surface 18s of the protruding portion 18 may be exposed to the outside of the first insulating layer 16 near the side surface 16s of the first insulating layer 16. The protruding portion 18 may be a portion of the first insulating layer 16, but, for convenience in description, distinct reference numbers may be used to describe the protruding portion 18 and the first insulating layer 16, respectively, in the present disclosure. Accordingly, the side surface 18s of the protruding portion 18 may be placed on the side surface 16s of the first insulating layer 16, and the side surface 18s of the protruding portion 18 and the side surface 16s of the first insulating layer 16 may form a single surface corresponding to the entire side surface of the first insulating layer 16. The side surfaces 16s and 18s may be substantially flat and may be substantially coplanar with each other.

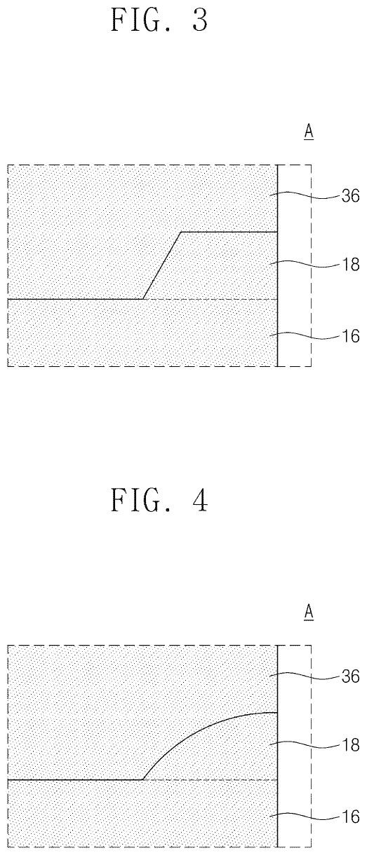

A sectional shape of the protruding portion 18 may be rectangle or square, as shown in FIG. 2. In some implementations, the protruding portion 18 may have a trapezoidal section, in which its top width is smaller than its bottom width, as shown in FIG. 3, or a fan-shaped section having an upward convex portion, as shown in FIG. 4. However, the protruding portion 18 is not limited to this example, and the sectional shape of the protruding portion 18 may be one of other various shapes (e.g., triangle) with an upward sharp portion. A width W of the protruding portion 18 may range from 1 μm to 3 μm. A height H of the protruding portion 18 may range from 1 μm to 5 μm.

In FIG. 5, the protruding portion 18 may be extended along the side surfaces of the lower structure 10. For example, the protruding portion 18 may have a closed loop shape that is extended along an edge of the lower structure 10, when viewed in a plan view. In the present disclosure, the term “closed loop shape” may refer to not only closed shapes with sharp portions, but also other closed shapes (e.g., tetragonal or polygonal ring) with sharp portions.

In FIGS. 1 and 2, the upper structure 30 may be provided on the lower structure 10. The upper structure 30 may include a second substrate 32, a second circuit layer 34, a second insulating layer 36, and second pads 40.

The second substrate 32 may be a semiconductor substrate (e.g., a semiconductor wafer). The second substrate 32 may be a bulk silicon substrate, a silicon-on-insulator (SOI) substrate, a germanium substrate, a germanium-on-insulator (GOI) substrate, a silicon-germanium substrate, or a substrate including an epitaxial layer grown using a selective epitaxial growth (SEG) technique. The second substrate 32 may be formed of or include at least one of silicon (Si), germanium (Ge), silicon germanium (SiGe), gallium arsenic (GaAs), indium gallium arsenic (InGaAs), or aluminum gallium arsenic (AlGaAs). Alternatively, the second substrate 32 may be an insulating substrate (e.g., a printed circuit board (PCB)).

The second circuit layer 34 may be disposed on a bottom surface of the second substrate 32. The second circuit layer 34 may include a second circuit pattern provided on the second substrate 32 and a second interlayer insulating layer covering the second circuit pattern. The second circuit pattern may be a memory circuit with one or more transistors, a logic circuit with one or more transistors, or combinations thereof. Alternatively, the second circuit pattern may include a passive device (e.g., a resistor, an inductor, or a capacitor).

The second pads 40 may be disposed on a bottom surface of the second circuit layer 34. The second pad 40 may be a pad electrically connected to the second circuit pattern of the second circuit layer 34. The second pads 40 may have substantially the same thickness. For example, the second pad 40 may have a plate-shape structure. In some implementations, the second pad 40 may include a via portion and a pad portion, which is provided under and connected to the via portion, and here, the via and pad portions of the second pad 40 may have a section in the inverted shape of the letter ‘T’ and may form a single object. A width of the second pad 40 may be substantially constant, regardless of a distance from the second substrate 32. Alternatively, the width of the second pad 40 may decrease as a distance to the second substrate 32 decreases. The second pads 40 may be arranged in a rectangular shape or in a honeycomb shape. The second pad 40 may have a circular, tetragonal, octagonal, or polygonal planar shape. The second pads 40 may be formed of or include at least one of metallic materials. For example, the second pads 40 may be formed of or include copper (Cu).

The second pads 40 may be electrically connected to the second circuit pattern of the second circuit layer 34. For example, a second connection pattern 35 may be provided in the second circuit layer 34, as shown in FIG. 1. The second connection pattern 35 may be a penetration via (e.g., a through-silicon via) that is provided to vertically penetrate the second interlayer insulating layer in the second circuit layer 34. The second connection pattern 35 may be vertically extended in the second circuit layer 34 and may be coupled to the second pads 40. The second connection pattern 35 may electrically connect the second circuit pattern to the second pads 40. In FIG. 1, various conductive patterns may be further provided for the interconnection between the second circuit pattern and the second connection pattern 35. Unlike the structure illustrated in FIG. 1, the second connection pattern 35 may be an under-pad pattern or a redistribution pattern, which is provided in an insulating pattern in the second circuit layer 34. Additionally, various conductive patterns may be further provided for the interconnection between the second circuit pattern and the second connection pattern 35. However, the conductive patterns are not limited to this example, and if necessary, the shape of the second circuit layer 34 may be variously changed and the electrical interconnection between the second pads 40 and the second circuit layer 34 may be achieved by other various structures.

The second pads 40 may have a damascene structure. For example, the second pads 40 may further include seed/barrier patterns covering side and top surfaces of the second pads 40, respectively. The seed/barrier patterns may conformally cover the side and top surfaces of the second pads 40. Where the seed/barrier patterns are used as a seed pattern, the seed/barrier patterns may be formed of or include at least one of metallic materials (e.g., gold (Au)). Where the seed/barrier patterns are used as a barrier pattern, the seed/barrier patterns may be formed of or include at least one of metallic materials (e.g., titanium (Ti) and tantalum (Ta)) or metal nitride materials (e.g., titanium nitride (TiN) and tantalum nitride (TaN)).

The second insulating layer 36 may be provided on the bottom surface of the second circuit layer 34 to enclose the second pads 40. Bottom surfaces of the second pads 40 may be exposed to the outside of the second insulating layer 36. For example, the second insulating layer 36 may enclose the second pads 40 but may not cover the second pads 40, when viewed in a plan view. A top surface of the second insulating layer 36 and a top surface of the second pad 40 may be substantially flat and may be substantially coplanar with each other. However, the second insulating layer 36 is not limited to this example. The second insulating layer 36 may include an oxide, nitride, or oxynitride material containing an element included in the second substrate 32 or the second circuit layer 34. The second insulating layer 36 may include at least one of insulating materials (e.g., silicon oxide (SiO), silicon nitride (SiN), silicon oxynitride (SiON), or silicon carbon nitride (SiCN)). For example, the second insulating layer 36 may be formed of or include silicon oxide (SiO).

The upper structure 30 may be disposed on the lower structure 10. The first pads 20 of the lower structure 10 and the second pads 40 of the upper structure 30 may be vertically aligned to each other. The lower and upper structures 10 and 30 may be in contact with each other.

The upper structure 30 may be connected to the lower structure 10. For example, the lower and upper structures 10 and 30 may be in contact with each other. The first pads 20 of the lower structure 10 and the second pads 40 of the upper structure 30 may be electrically connected to each other. For example, the lower and upper structures 10 and 30 may be in contact with each other. At an interface between the lower and upper structures 10 and 30, the first pads 20 of the lower structure 10 may be bonded to the second pads 40 of the upper structure 30. Here, the first and second pads 20 and 40 may form an intermetal hybrid bonding structure. In the present disclosure, the hybrid bonding structure may indicate a bonding structure that is formed by two materials, which are of the same kind and are fused at an interface therebetween. For example, the first and second pads 20 and 40, which are bonded to each other, may have a continuous structure, and an interface between the first and second pads 20 and 40 may not be visible or observable. For example, the first and second pads 20 and 40 may be formed of the same material, and in this case, there may be no visible or observable interface between the first and second pads 20 and 40. In some implementations, the first and second pads 20 and 40 may be provided as a single object. For example, the first and second pads 20 and 40 may be bonded to form a single object.

As a result of the bonding of the lower and upper structures 10 and 30, the first and second insulating layers 16 and 36 may be in contact with each other. In some implementations, the protruding portion 18 of the first insulating layer 16 may be inserted in the second insulating layer 36.

The side surface of the lower structure 10 may be vertically aligned to the side surface of the upper structure 30. For example, the side surface of the lower structure 10 may be coplanar with the side surface of the upper structure 30. The side surface 16s of the first insulating layer 16 may be coplanar with a side surface 36s of the second insulating layer 36.

According to some implementations, the first insulating layer 16 of the lower structure 10 may be provided to include the protruding portion 18. The protruding portion 18 may prevent a process failure (e.g., a detachment issue between the first and second insulating layers 16 and 36 caused by horizontal crack propagation) in a singulation process, which is performed as a part of a fabrication process of the semiconductor package. The first and second insulating layers 16 and 36 may be robustly bonded to each other, and the lower and upper structures 10 and 30 may be robustly bonded to each other. Accordingly, it may be possible to improve the structural stability of the semiconductor package.

In the description of the implementations explained below, an element previously described with reference to FIGS. 1 to 5 may be identified by the same reference number without repeating an overlapping description thereof, for concise description.

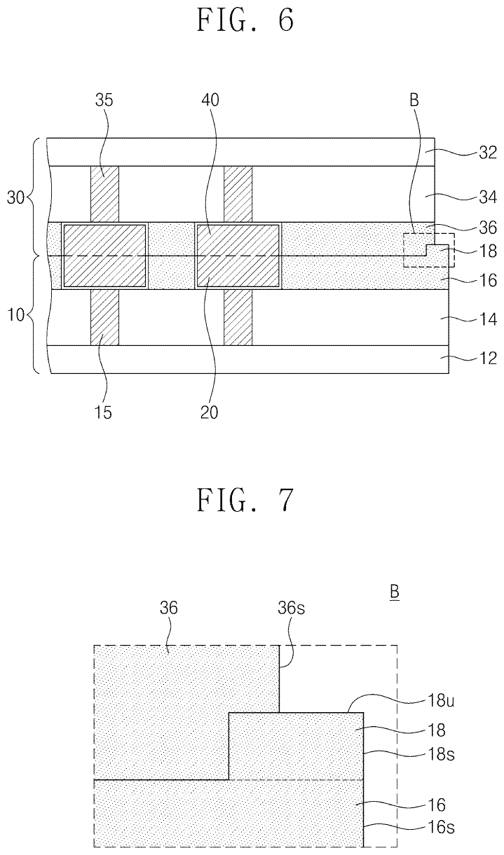

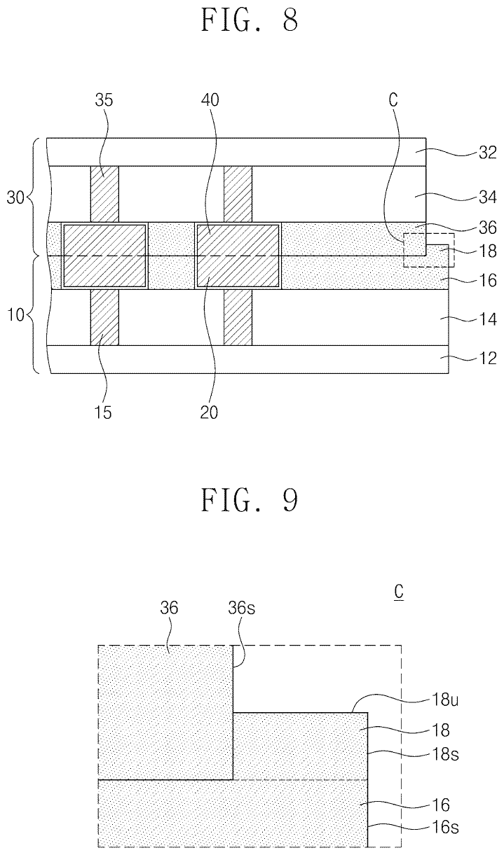

FIG. 6 is a sectional view illustrating an example of a semiconductor package according to some implementations. FIG. 7 is an enlarged view illustrating an example of a portion ‘B’ of FIG. 6 according to some implementations. FIG. 8 is a sectional view illustrating an example of a semiconductor package according to some implementations. FIG. 9 is an enlarged view illustrating an example of a portion ‘C’ of FIG. 8 according to some implementations.

FIGS. 1 to 5 illustrate implementations, in which the side surface of the lower structure 10 is vertically aligned to the side surface of the upper structure 30. However, the implementations in FIGS. 1 to 5 are not limited to this configuration.

In FIGS. 6 and 7, the side surface of the lower structure 10 and the side surface of the upper structure 30 may form a stepwise structure near a bonding surface between the lower and upper structures 10 and 30. The lower structure 10 may protrude outward from the side surface of the upper structure 30. For example, the first insulating layer 16 may protrude outward from the side surface 36s of the second insulating layer 36. The side surface 36s of the second insulating layer 36 may be located on a top surface 18u of the protruding portion 18. For example, the side surface 36s of the second insulating layer 36 may be located between an outer side surface 18s and an inner side surface of the protruding portion 18. Accordingly, a portion of the top surface 18u of the protruding portion 18 may be exposed to the outside, on the side surface 36s of the second insulating layer 36.

In FIGS. 8 and 9, the side surface of the lower structure 10 and the side surface of the upper structure 30 may form a stepwise structure near the bonding surface between the lower and upper structures 10 and 30. The lower structure 10 may protrude outward from the side surface of the upper structure 30. The side surface 36s of the second insulating layer 36 may be aligned to the inner side surface of the protruding portion 18. Accordingly, the entire top surface 18u of the protruding portion 18 may be exposed to the outside, on the side surface 36s of the second insulating layer 36.

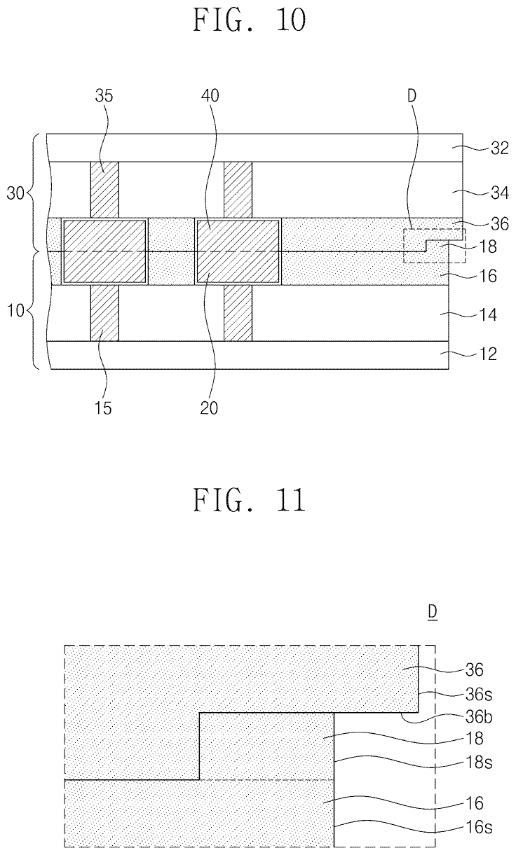

FIG. 10 is a sectional view illustrating an example of a semiconductor package according to some implementations. FIG. 11 is an enlarged view illustrating an example of a portion ‘D’ of FIG. 10 according to some implementations.

In FIGS. 10 and 11, the side surface of the lower structure 10 and the side surface of the upper structure 30 may form a stepwise structure near at the bonding surface between the lower and upper structures 10 and 30. The upper structure 30 may protrude outward from the side surface of the lower structure 10. For example, the second insulating layer 36 may protrude outward from the side surface 16s of the first insulating layer 16. The entire top surface 18u of the protruding portion 18 may be in contact with the second insulating layer 36. Accordingly, on the side surface 16s of the first insulating layer 16, a portion of a bottom surface 36b of the second insulating layer 36 may be exposed to the outside.

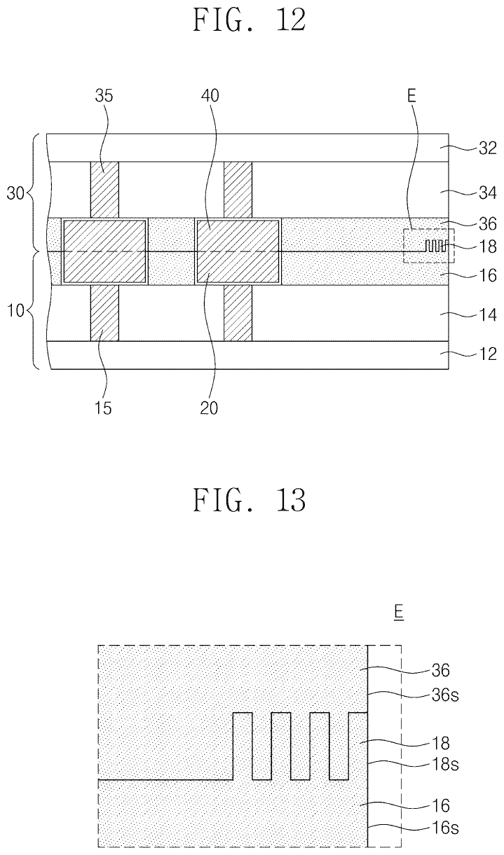

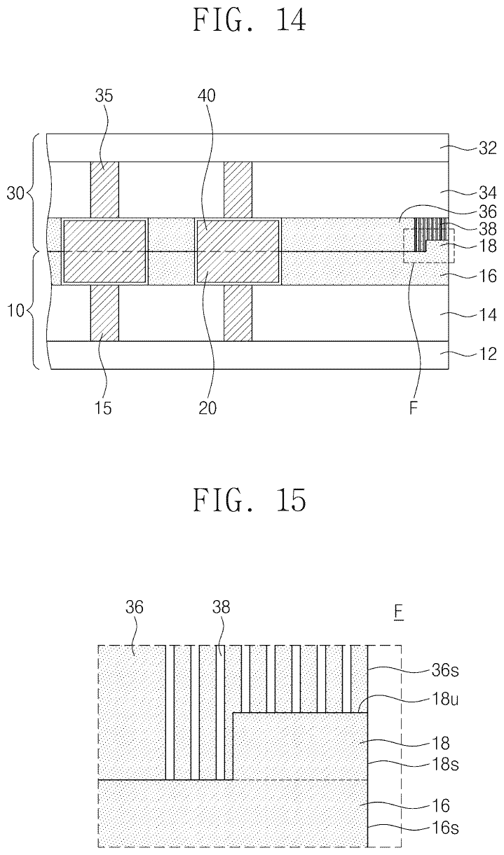

FIG. 12 is a sectional view illustrating an example of a semiconductor package according to some implementations. FIG. 13 is an enlarged view illustrating an example of a portion ‘E’ of FIG. 12 according to some implementations.

In FIGS. 12 and 13, a plurality of protruding portions 18 may be provided. The protruding portions 18 may be horizontally spaced apart from each other. For example, the protruding portions 18 may be spaced apart from each other in a direction from the side surface of the lower structure 10 toward a center portion of the lower structure 10. Each of the protruding portions 18 may be extended along an edge of the lower structure 10 and may have a closed loop shape, when viewed in a plan view. The side surface 18s of the outermost one of the protruding portions 18 may be coplanar with the side surface 16s of the first insulating layer 16.

The side surface 36s of the second insulating layer 36 may be located on a top surface of one of the protruding portions 18. In FIGS. 12 and 13, the side surface 36s of the second insulating layer 36 is located on a top surface of the outermost one of the protruding portions 18, but the inventive concept is not limited to this example. For example, the side surface 36s of the second insulating layer 36 may be placed on a top surface of another one of the protruding portions 18.

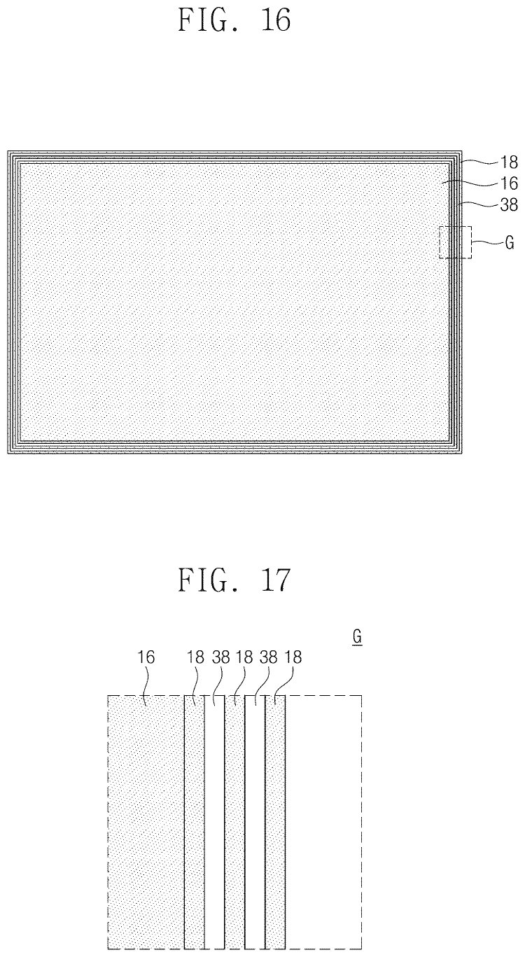

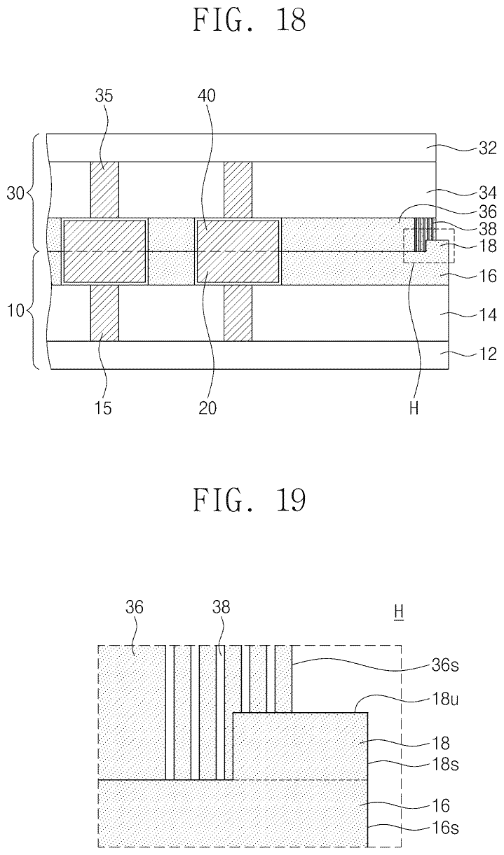

FIG. 14 is a sectional view illustrating an example of a semiconductor package according to some implementations. FIG. 15 is an enlarged view illustrating an example of a portion ‘F’ of FIG. 14 according to some implementations. FIG. 16 is a plan view illustrating an example of semiconductor package according to some implementations. FIG. 17 is an enlarged view illustrating an example of a portion ‘G’ of FIG. 16 according to some implementations.

In FIGS. 14 to 17, the upper structure 30 may further include slit structures 38. The slit structures 38 may be disposed in the second insulating layer 36. The slit structures 38 may vertically penetrate the second insulating layer 36 and may be exposed through a bottom surface of the second insulating layer 36. The slit structures 38 may be horizontally spaced apart from each other. For example, the slit structures 38 may be spaced apart from each other in a direction from the side surface of the upper structure 30 toward a center portion of the upper structure 30. Each of the slit structures 38 may be extended along an edge of the upper structure 30 and may have a closed loop shape, when viewed in a plan view.

At the bonding surface between the lower and upper structures 10 and 30, at least one of the slit structures 38 may be in contact with the top surface 18u of the protruding portion 18. On the inner side surface of the protruding portion 18 facing the center portion of the lower structure 10, others of the slit structures 38 may be in contact with the top surface 16u of the first insulating layer 16. However, the slit structures 38 are not limited to this example, and the entirety of the slit structures 38 may be placed on the top surface 18u of the protruding portion 18. The slit structures 38 may be an empty space filled with the air or may be formed of or include an insulating material.

According to some implementations, the slit structures 38 may be provided in the second insulating layer 36 of the upper structure 30. The slit structure 38 may prohibit a crack from horizontally propagating in a singulation process, which is performed as a part of a fabrication process of the semiconductor package. For example, it may be possible to suppress a process failure (e.g., a detachment issue between the first and second insulating layers 16 and 36) caused by the horizontal crack propagation. Accordingly, the first and second insulating layers 16 and 36 may be robustly bonded to each other, and the lower and upper structures 10 and 30 may be robustly bonded to each other. In other words, it may be possible to improve the structural stability of the semiconductor package.

FIG. 18 is a sectional view illustrating an example of a semiconductor package according to some implementations. FIG. 19 is an enlarged view illustrating an example of a portion ‘H’ of FIG. 18 according to some implementations.

In FIGS. 18 and 19, the side surface of the lower structure 10 and the side surface of the upper structure 30 may form a stepwise structure near the bonding surface between the lower and upper structures 10 and 30. The lower structure 10 may protrude outward from the side surface of the upper structure 30. For example, the first insulating layer 16 may protrude outward from the side surface 36s of the second insulating layer 36. The side surface 36s of the second insulating layer 36 may be located on the top surface 18u of the protruding portion 18. The slit structures 38 may be provided in the second insulating layer 36. Some of the slit structures 38 may be placed on the top surface 18u of the protruding portion 18, and others of the slit structures 38 may be placed on the inner side surface of the protruding portion 18. In some implementations, the slit structures 38 may not be provided on the top surface 18u of the protruding portion 18 and may be provided on only the inner side surface of the protruding portion 18.

Alternatively, the side surface 36s of the second insulating layer 36 may be aligned to the inner side surface of the protruding portion 18. Accordingly, the entire top surface 18u of the protruding portion 18 may be exposed to the outside, on the side surface 36s of the second insulating layer 36. Here, the slit structures 38 may be provided on the inner side surface of the protruding portion 18.

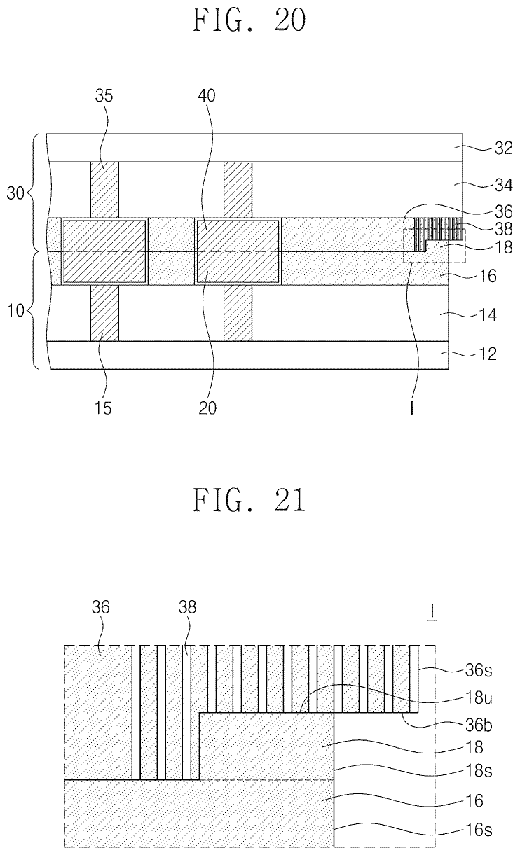

FIG. 20 is a sectional view illustrating an example of a semiconductor package according to some implementations. FIG. 21 is an enlarged view illustrating an example of a portion ‘I’ of FIG. 20 according to some implementations.

In FIGS. 20 and 21, the side surface of the lower structure 10 and the side surface of the upper structure 30 may form a stepwise structure near the bonding surface between the lower and upper structures 10 and 30. The upper structure 30 may protrude outward from the side surface of the lower structure 10. For example, the second insulating layer 36 may protrude outward from the side surface 16s of the first insulating layer 16. The entire top surface 18u of the protruding portion 18 may be in contact with the second insulating layer 36. Accordingly, on the side surface 16s of the first insulating layer 16, a portion of a bottom surface 36b of the second insulating layer 36 may be exposed to the outside. The slit structures 38 may be provided in the second insulating layer 36. Some of the slit structures 38 may be placed on the top surface 18u of the protruding portion 18, and others of the slit structures 38 may be placed on the inner side surface of the protruding portion 18. Still others of the slit structures 38 may be placed on the outer side surface 18s of the protruding portion 18. Accordingly, bottom surfaces of the still others of the slit structures 38 may be exposed to the outside, at a side of the lower structure 10.

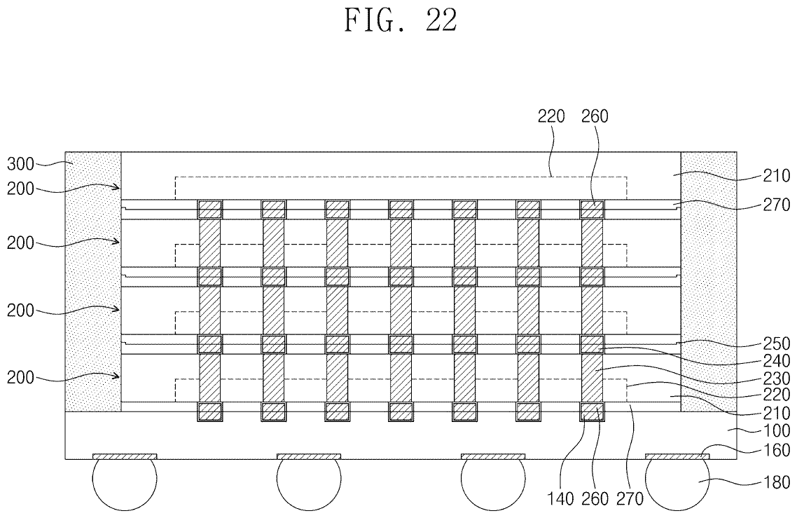

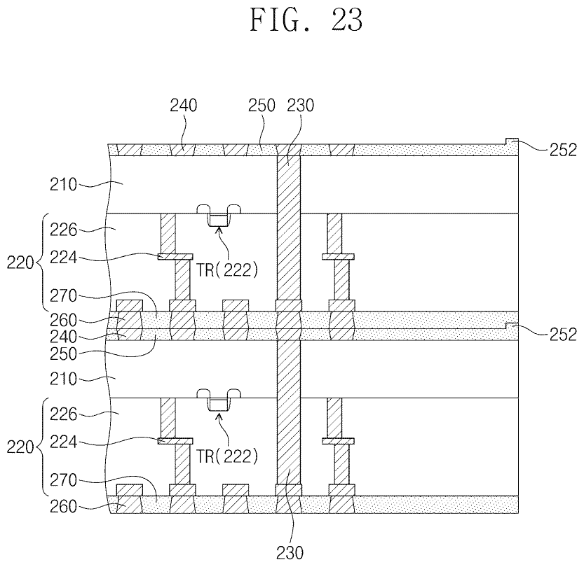

FIG. 22 is a sectional view illustrating an example of a semiconductor package according to some implementations. FIG. 23 is an enlarged view illustrating an example of a portion of FIG. 22 according to some implementations.

In FIGS. 22 and 23, a base substrate 100 may be provided. The base substrate 100 may be a substrate (e.g., a printed circuit board (PCB)), in which an electronic element (e.g., a transistor) is not provided. The base substrate 100 may include first substrate pads 140 and second substrate pads 160. The first substrate pads 140 may be exposed to the outside of the base substrate 100 near a top surface of the base substrate 100. A top surface of the first substrate pads 140 may be coplanar with the top surface of the base substrate 100. The second substrate pads 160 may be exposed to the outside of the base substrate 100 near a bottom surface of the base substrate 100. A bottom surface of the second substrate pads 160 may be coplanar with the bottom surface of the base substrate 100. The first substrate pads 140 may be electrically connected to the second substrate pads 160 through an interconnection in the base substrate 100. The first and second substrate pads 140 and 160 may include at least one of metallic materials. For example, the first and second substrate pads 140 and 160 may be formed of or include copper (Cu).

Outer terminals 180 may be provided on the bottom surface of the base substrate 100. The outer terminals 180 may be disposed on the second substrate pads 160. The outer terminal 180 may be formed of or include an alloy containing at least one of tin (Sn), silver (Ag), copper (Cu), nickel (Ni), bismuth (Bi), indium (In), antimony (Sb), or cerium (Ce).

In FIG. 22, the base substrate 100 is a printed circuit board, but the base substrate 100 is not limited to this implementation. In some implementations, the base substrate 100 may include an integrated circuit provided therein. For example, the base substrate 100 may be a first semiconductor chip including an electronic element (e.g., a transistor). For example, the base substrate 100 may be a wafer-level die that is formed of a semiconductor material (e.g., silicon (Si)). The first semiconductor chip 100 may include a first semiconductor substrate, a first circuit layer including integrated circuits formed on the first semiconductor substrate, first vias vertically penetrating the first semiconductor substrate, first upper pads provided on a top surface of the first semiconductor substrate, a first upper protection layer provided on the top surface of the first semiconductor substrate to enclose the first upper pads, first lower pads provided on a bottom surface of the first semiconductor substrate, and a first lower protection layer provided on the bottom surface of the first semiconductor substrate to enclose the first lower pads.

Second semiconductor chips 200 may be stacked on the first semiconductor chip 100. The second semiconductor chips 200 may be of the same kind. For example, the second semiconductor chips 200 may be memory chips. In some implementations, four second semiconductor chips 200 are provided, but the number of the second semiconductor chips 200 is not limited to this implementation. For example, the number of the second semiconductor chips 200 may be changed to one of 2, 3, 5, or higher, if necessary. Hereinafter, the structure of the second semiconductor chips 200 will be described in more detail with reference to one of the second semiconductor chips 200.

The second semiconductor chip 200 may include a second semiconductor substrate 210, a second circuit layer 220, a second via 230, a second upper pad 240, a second upper protection layer 250, a second lower pad 260, and a second lower protection layer 270. The second semiconductor substrate 210 may include a semiconductor material. For example, the second semiconductor substrate 210 may be a single-crystalline silicon substrate. A bottom surface of the second semiconductor substrate 210 may be a front surface of the second semiconductor substrate 210, and a top surface of the second semiconductor substrate 210 may be a rear surface of the second semiconductor substrate 210. Here, the front surface of the second semiconductor substrate 210 may be defined as a surface of the second semiconductor substrate 210, on which semiconductor devices, interconnection lines, or pads are formed or mounted, and the rear surface of the second semiconductor substrate 210 may be defined as a surface that is opposite to the front surface.

The second semiconductor chip 200 may include the second circuit layer 220 that is provided to face the base substrate 100. The second circuit layer 220 may include a semiconductor device 222 and a device interconnection portion 224.

The semiconductor device 222 may include one or more transistors TR that are provided on the bottom surface of the second semiconductor substrate 210. The semiconductor device 222 may include a memory circuit, a logic circuit, or a passive device.

The bottom surface of the second semiconductor substrate 210 may be covered with a device interlayer insulating layer 226. The device interlayer insulating layer 226 may be provided on the bottom surface of the second semiconductor substrate 210 to bury the semiconductor device 222. The device interlayer insulating layer 226 may be formed of or include at least one of, for example, silicon oxide (SiO), silicon nitride (SiN), or silicon oxynitride (SiON). Alternatively, the device interlayer insulating layer 226 may be formed of or include at least one of low-k dielectric materials.

The device interconnection portion 224, which is connected to the transistors TR, may be provided in the device interlayer insulating layer 226. The device interconnection portion 224 may include interconnection patterns, which are used for the horizontal interconnection, and connection contacts, which are used for the vertical interconnection. A portion of the device interconnection portion 224 may be exposed to the outside of the device interlayer insulating layer 226 through a bottom surface of the device interlayer insulating layer 226. For example, the portion of the device interconnection portion 224 may be the lowermost ones of the interconnection patterns of the device interconnection portion 224. The interconnection patterns may be formed of or include at least one of, for example, copper (Cu) or tungsten (W).

The semiconductor device 222, the device interlayer insulating layer 226, and the device interconnection portion 224 may constitute the second circuit layer 220.

The second vias 230 may vertically penetrate the second semiconductor substrate 210 and may be connected to the device interconnection portion 224. The second vias 230 may vertically penetrate the device interlayer insulating layer 226 and the second semiconductor substrate 210 and may be exposed to the outside through the top surface of the second semiconductor substrate 210. In some implementations, the second vias 230 may be formed of or include tungsten (W).

The second lower pads 260 may be disposed on the device interlayer insulating layer 226. The second lower pads 260 may be coupled to the device interconnection portion 224 and the second vias 230. The second lower pads 260 may be electrically connected to the semiconductor device 222 through the device interconnection portion 224. The second lower pads 260 may include a metallic material. For example, the second lower pads 260 may be formed of or include copper (Cu).

The second lower protection layer 270 may be disposed on the device interlayer insulating layer 226. For example, the second lower protection layer 270 may be provided on the bottom surface of the device interlayer insulating layer 226 to enclose the second lower pads 260. The second lower pads 260 may be exposed to the outside of the second lower protection layer 270. A bottom surface of the second lower protection layer 270 may be coplanar with bottom surfaces of the second lower pads 260. The second lower protection layer 270 may be formed of or include at least one of silicon nitride (SiN), silicon oxide (SiO), silicon oxycarbide (SiOC), silicon oxynitride (SiON), or silicon carbon nitride (SiCN).

The second upper pads 240 may be disposed on the top surface of the second semiconductor substrate 210. At least some of the second upper pads 240 may be coupled to the second vias 230. The second upper pads 240 may include a metallic material. For example, the second upper pads 240 may be formed of or include copper (Cu).

The second upper protection layer 250 may be disposed on the top surface of the second semiconductor substrate 210. The second upper protection layer 250 on the second semiconductor substrate 210 may enclose the second upper pads 240. The second upper pads 240 may be exposed to the outside of the second upper protection layer 250. A top surface of the second upper protection layer 250 may be coplanar with top surfaces of the second upper pads 240. The second upper protection layer 250 may be formed of or include at least one of silicon nitride (SiN), silicon oxide (SiO), silicon oxycarbide (SiOC), silicon oxynitride (SiON), or silicon carbon nitride (SiCN).

The second upper protection layer 250 may include a protruding portion 252. The protruding portion 252 may be placed at a level higher than the top surface of the second upper protection layer 250. A side surface of the protruding portion 252 may be exposed outward from a side surface of the second upper protection layer 250. The protruding portion 252 may be extended along the side surface of the second semiconductor chip 200. As an example, the protruding portion 252 may have a closed loop shape that is extended along an edge of the second semiconductor chip 200, when viewed in a plan view.

The second semiconductor chips 200 may have substantially the same structure, but the uppermost one of the second semiconductor chips 200 may not include the second via 230, the second upper pad 240, and the second upper protection layer 250. However, the second semiconductor chips 200 are not limited to this implementation.

The second semiconductor chips 200 may be sequentially stacked on the base substrate 100. The second semiconductor chips 200 may be bonded to each other by a method that is the same as or similar to the afore-described method of bonding the lower and upper structures 10 and 30 described with reference to FIGS. 1 to 21. For example, a lower one of the second semiconductor chips 200, which are bonded to each other, may correspond to the lower structure 10 described with reference to FIGS. 1 to 21, and an upper one of such second semiconductor chips 200 may correspond to the upper structure 30 described with reference to FIGS. 1 to 21. Hereinafter, the stacking structure of the second semiconductor chips 200 will be described with reference to a pair of the second semiconductor chips 200 which are bonded to each other.

The second upper pads 240 in a lower one of the second semiconductor chips 200 may be vertically aligned to the second lower pads 260 in an upper one of the second semiconductor chips 200. The second semiconductor chips 200 may be in contact with each other. At an interface between the second semiconductor chips 200, the second upper pads 240 in the lower one of the second semiconductor chips 200 may be bonded to the second lower pads 260 in the upper one of the second semiconductor chips 200. Here, the second upper pad 240 and the second lower pad 260 may form an intermetal hybrid bonding structure. For example, the second upper pad 240 and the second lower pad 260, which are bonded to each other, may have a continuous structure, and thus, an interface between the second upper pad 240 and the second lower pad 260 may not be visible or observable. For example, the second upper pads 240 and the second lower pads 260 may be formed of the same material, and in this case, there may be no visible or observable interface between the second upper pads 240 and the second lower pads 260. In some implementations, the second upper pad 240 and the second lower pad 260 may be provided as a single object. For example, the second upper pad 240 and the second lower pad 260 may be bonded to form a single object.

As a result of the bonding of the second semiconductor chips 200, the second upper protection layer 250 in a lower one of the second semiconductor chips 200 may be in contact with the second lower protection layer 270 in an upper one of the second semiconductor chip 200. Here, the protruding portion 252 may be inserted in the second lower protection layer 270.

The lowermost one of the second semiconductor chips 200 may be mounted on the base substrate 100. For example, the second lower pads 260 of the lowermost one of the second semiconductor chips 200 may be directly bonded to the first substrate pads 140 of the base substrate 100, or the lowermost one of the second semiconductor chips 200 may be bonded to the base substrate 100 using connection terminals (e.g., solder balls) provided between the first substrate pads 140 and the second lower pads 260.

A mold layer 300 may be provided on the base substrate 100. On the top surface of the base substrate 100, the mold layer 300 may enclose the second semiconductor chips 200. The mold layer 300 may include an insulating material. For example, the mold layer 300 may include an epoxy molding compound (EMC). Additionally, the mold layer 300 may be formed to cover the second semiconductor chips 200.

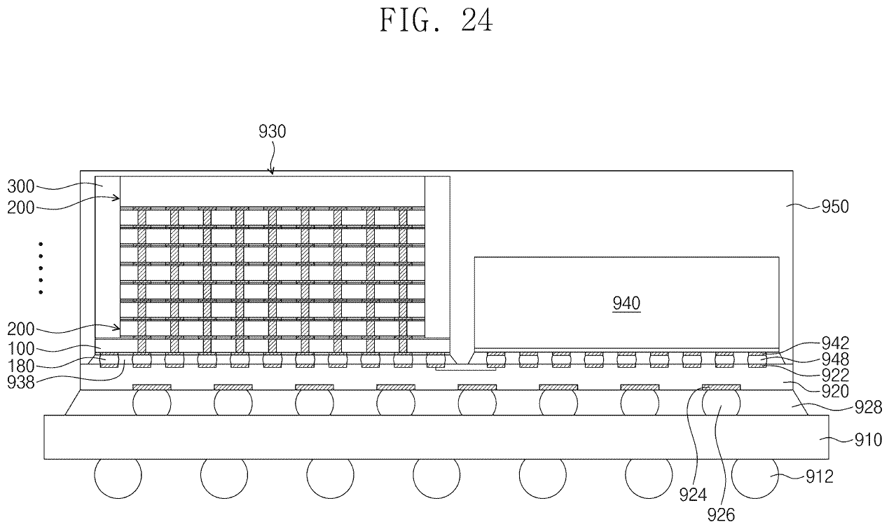

FIG. 24 is a sectional view illustrating an example of a semiconductor module according to some implementations. In FIG. 24, the semiconductor module may include a module substrate 910, a chip stack package 930 and a graphics processing unit 940, which are mounted on the module substrate 910, and an outer mold layer 950 covering the chip stack package 930 and the graphics processing unit 940, and in an embodiment, it may be a memory module. The semiconductor module may further include an interposer 920 provided on the module substrate 910.

The module substrate 910 may be provided. The module substrate 910 may include a printed circuit board (PCB) having signal patterns, which are formed on a top surface thereof.

Module terminals 912 may be disposed below the module substrate 910. The module substrate 910 may include solder balls or solder bumps, and the semiconductor module may be classified into a ball grid array (BGA) type, a fine ball-grid array (FBGA) type, or a land grid array (LGA) type, depending on the kind and structure of the module substrate 910.

The interposer 920 may be provided on the module substrate 910. The interposer 920 may include first substrate pads 922 and second substrate pads 924, which are respectively placed on top and bottom surfaces of the interposer 920 and are exposed to the outside of the interposer 920. The interposer 920 may be configured to provide a redistribution structure for the chip stack package 930 and the graphics processing unit 940. The interposer 920 may be mounted on the module substrate 910 in a flip chip manner. For example, the interposer 920 may be mounted on the module substrate 910 using substrate terminals 926, which are provided on the second substrate pads 924. The substrate terminals 926 may include solder balls or solder bumps. A first under-fill layer 928 may be provided between the module substrate 910 and the interposer 920.

The chip stack package 930 may be disposed on the interposer 920. The chip stack package 930 may have the same or similar structure as the semiconductor package described with reference to FIGS. 22 and 23.

The chip stack package 930 may be mounted on the interposer 920. For example, the chip stack package 930 may be coupled to the first substrate pads 922 of the interposer 920 through the base substrate 100 or the outer terminals 180 of the first semiconductor chip 100. A second under-fill layer 932 may be provided between the chip stack package 930 and the interposer 920. The second under-fill layer 932 may fill a space between the interposer 920 and the base substrate (or the first semiconductor chip 100) and may enclose the base substrate 100 or the outer terminals 180 of the first semiconductor chip 100.

The graphics processing unit 940 may be disposed on the interposer 920. The graphics processing unit 940 may be spaced apart from the chip stack package 930. A thickness of the graphics processing unit 940 may be larger than a thickness of each of the semiconductor chips 100 and 200 of the chip stack package 930. The graphics processing unit 940 may include a logic circuit. For example, the graphics processing unit 940 may be a logic chip. Bumps 942 may be provided on a bottom surface of the graphics processing unit 940. For example, the graphics processing unit 940 may be coupled to the first substrate pads 922 of the interposer 920 through the bumps 942. A third under-fill layer 944 may be provided between the interposer 920 the graphics processing unit 940. Third under-fill layer 944 may fill a space between the interposer 920 and the graphics processing unit 940 and may enclose the bumps 942.

The outer mold layer 950 may be provided on the interposer 920. The outer mold layer 950 may cover the top surface of the interposer 920. The outer mold layer 950 may enclose the chip stack package 930 and the graphics processing unit 940. A top surface of the outer mold layer 950 may be located at the same level as a top surface of the chip stack package 930. The outer mold layer 950 may include an insulating material. For example, the outer mold layer 950 may include an epoxy molding compound (EMC).

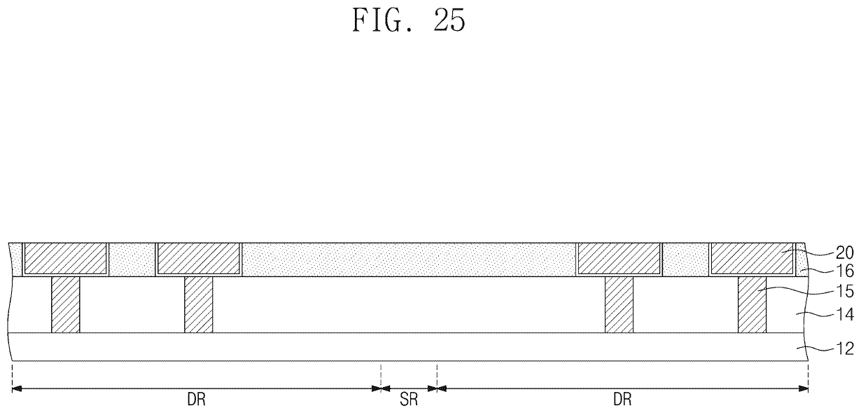

FIGS. 25 to 35 are sectional views illustrating an example of a method of fabricating a semiconductor package according to some implementations. In FIG. 25, the first substrate 12 may be provided. The first substrate 12 may be a semiconductor substrate. The first substrate 12 may include device regions DR and a scribe lane region SR between the device regions DR. The device regions DR may be regions, in which semiconductor packages will be formed, and the scribe lane region SR may be a region, on which a sawing process to separate the semiconductor packages from each other will be performed.

The first circuit layer 14 may be formed on the first substrate 12. The first circuit layer 14 may include the first connection pattern 15, which are used to connect the first substrate 12 to the first pads 20. The first connection pattern 15 may be formed on the device regions DR.

The first insulating layer 16 may be formed by depositing an insulating material on the first circuit layer 14. The first insulating layer 16 may cover the first circuit layer 14.

The first pads 20 may be formed on the first circuit layer 14. For example, the formation of the first pads 20 may include patterning the first insulating layer 16 to form openings exposing the first connection pattern 15, forming a seed/barrier layer to conformally cover the top surface of the first insulating layer 16 and side and bottom surfaces of the openings, forming a conductive layer through a plating process using the seed/barrier layer as a seed, and performing a polishing process on the conductive layer to expose the top surface of the first insulating layer 16. However, the inventive concept is not limited to this example, and the first pads 20 may be formed using other various methods.

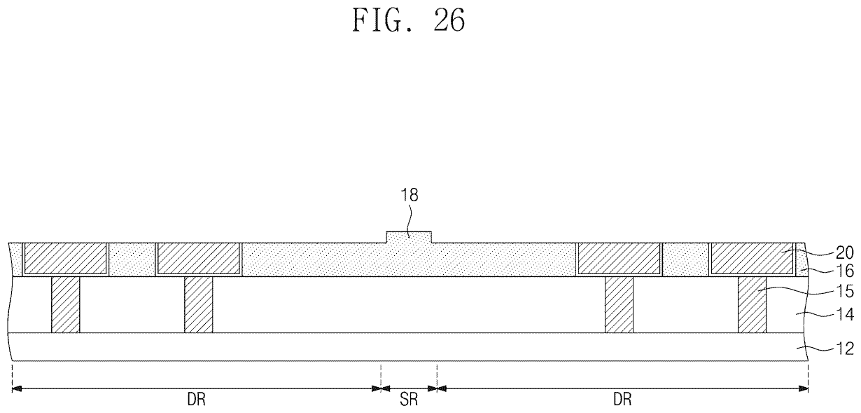

In FIG. 26, the protruding portion 18 may be formed on the first insulating layer 16. For example, the protruding portion 18 may be formed by forming an insulating layer on the first insulating layer 16 and patterning the insulating layer. The protruding portion 18 may be located on the scribe lane region SR. The insulating layer may be formed of the same material as the first insulating layer 16. Accordingly, there may be no border between the protruding portion 18 and the first insulating layer 16, and hereinafter, the protruding portion 18 may be referred to as a portion of the first insulating layer 16. In some implementations, the protruding portion 18 may be formed by patterning the first insulating layer 16. For example, the protruding portion 18 may be formed by etching the first insulating layer 16 on the device regions DR, not the scribe lane region SR.

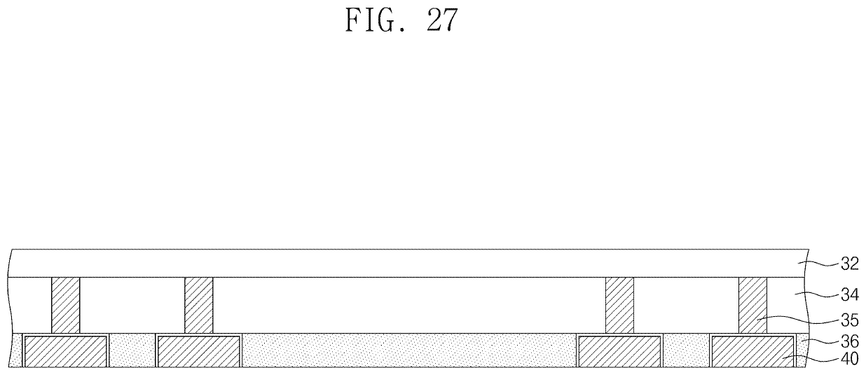

In FIG. 27, the second substrate 32 may be provided. The second substrate 32 may be a semiconductor substrate. The second circuit layer 34 may be formed on the second substrate 32. The second circuit layer 34 may include the second connection pattern 35, which is used to connect the second substrate 32 to the second pads 40.

The second insulating layer 36 may be formed by depositing an insulating material on the second circuit layer 34. The second insulating layer 36 may cover the second circuit layer 34.

The second pads 40 may be formed on the second circuit layer 34. For example, the formation of the second pads 40 may include patterning the second insulating layer 36 to form openings exposing the second connection pattern 35, forming a seed/barrier layer to conformally cover the top surface of the second insulating layer 36 and side and bottom surfaces of the openings, forming a conductive layer through a plating process using the seed/barrier layer as a seed, and performing a polishing process on the conductive layer to expose the top surface of the second insulating layer 36. However, the second pads 40 are not limited to this implementation, and the second pads 40 may be formed using various methods.

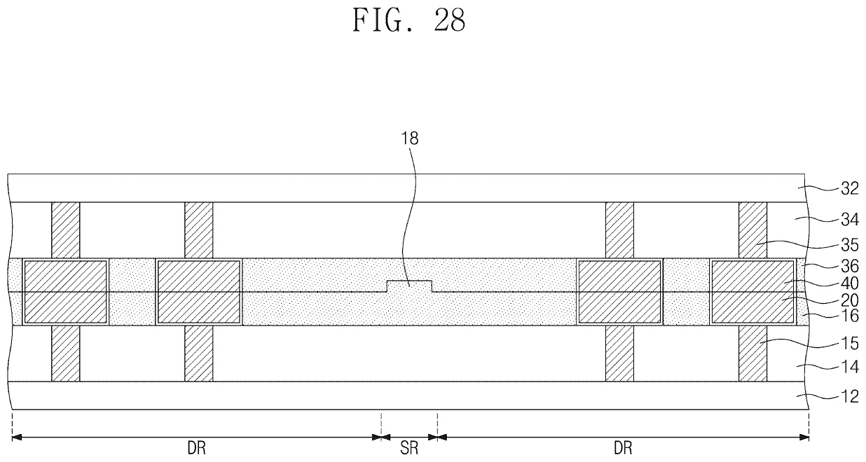

In FIG. 28, the second substrate 32 may be provided on the first substrate 12. For example, the second substrate 32 may be placed on the first substrate 12 such that the first and second pads 20 and 40 are vertically aligned to each other.

Accordingly, a distance between the first and second substrates 12 and 32 may be decreased in such a way that the first and second insulating layers 16 and 36 are in contact with each other. The top surface of the first insulating layer 16 may be in contact with the bottom surface of the second insulating layer 36. Top surfaces of the first pads 20 may be in contact with bottom surfaces of the second pads 40. Here, the protruding portion 18 may be inserted into the second insulating layer 36.

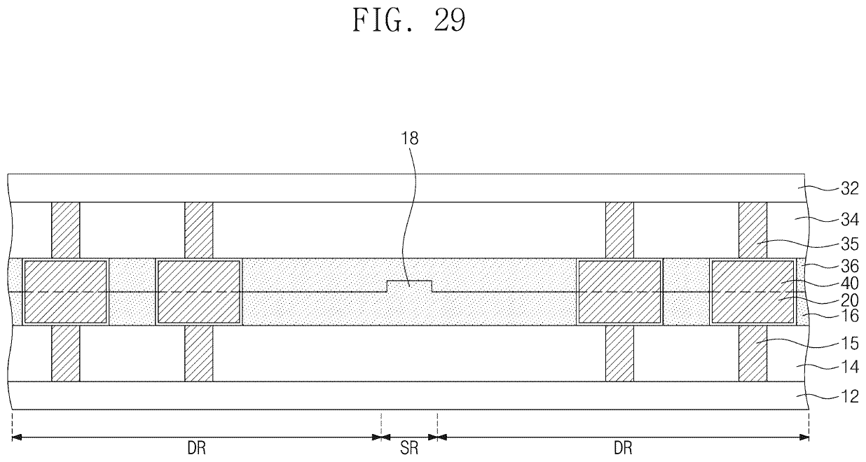

In FIG. 29, a thermal treatment process may be performed on the resulting structure of FIG. 28. As a result of the thermal treatment process, the first and second pads 20 and 40 may be bonded to each other. The bonding of the first and second pads 20 and 40 may be achieved in a natural manner. For example, the first and second pads 20 and 40 may be formed of the same material (e.g., copper (Cu)), and in this case, the first and second pads 20 and 40 may be bonded to each other by an intermetal hybrid bonding process, which is caused by a surface activation at an interface between the first and second pads 20 and 40 in contact with each other. Accordingly, the first and second pads 20 and 40 may be bonded to form a single object, and there may be no visible or observable interface between the first and second pads 20 and 40.

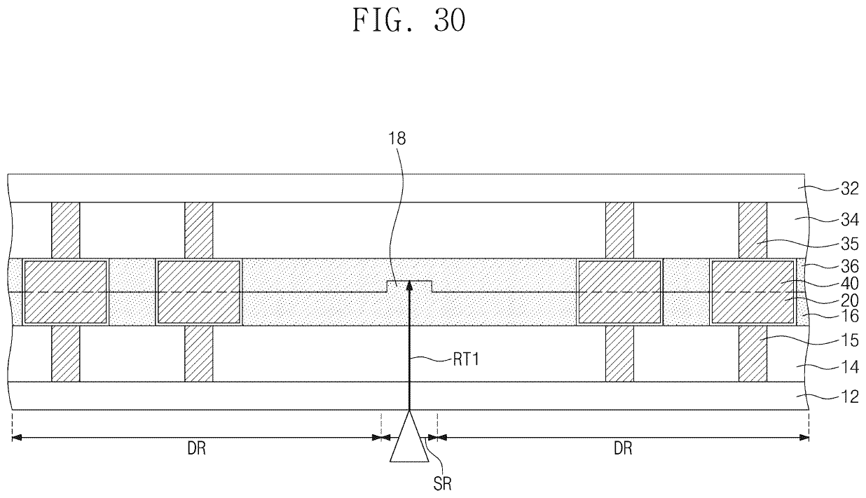

In FIGS. 30 to 35, a singulation process may be performed on the resulting structure of FIG. 29 to form semiconductor packages that are separated from each other. Hereinafter, the singulation process will be described in more detail.

In FIG. 30, a crack may be formed in the first substrate 12. The crack may be formed in the scribe lane region SR. For example, the first substrate 12 may be irradiated with a laser beam. The irradiation of the laser beam may cause the crack in the first substrate 12 or in the bottom surface of the first substrate 12.

Next, the crack in the first substrate 12 may propagate in a specific direction. When the crack propagates, a cracked portion may extend in a structure in a specific direction. For example, the crack in the first substrate 12 may propagate along a first propagation path RT1 depicted by the arrow of FIG. 30. The first propagation path RT1 may be a path that is extended from an inner portion of the first substrate 12 to a top surface of the protruding portion 18 through the first circuit layer 14, the first insulating layer 16, and the protruding portion 18 of the first insulating layer 16 in a vertical direction. The propagation of the crack may be achieved in a natural manner or may be caused by applying a stress on or the first substrate 12 or the entire structure of FIG. 30.

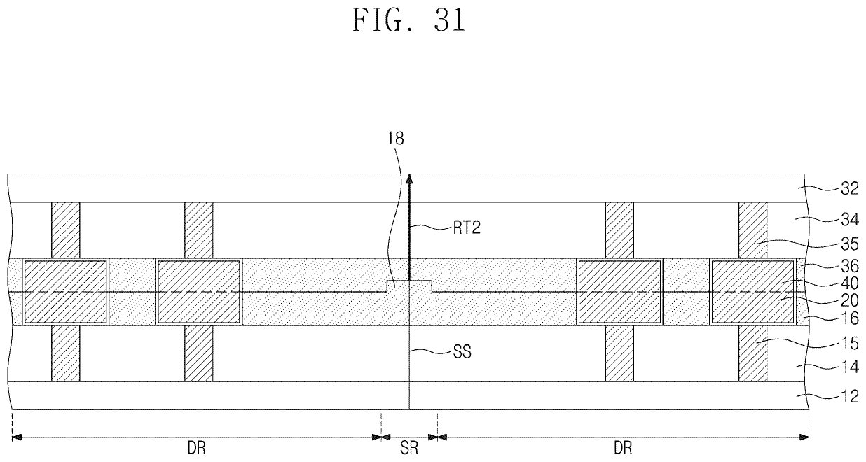

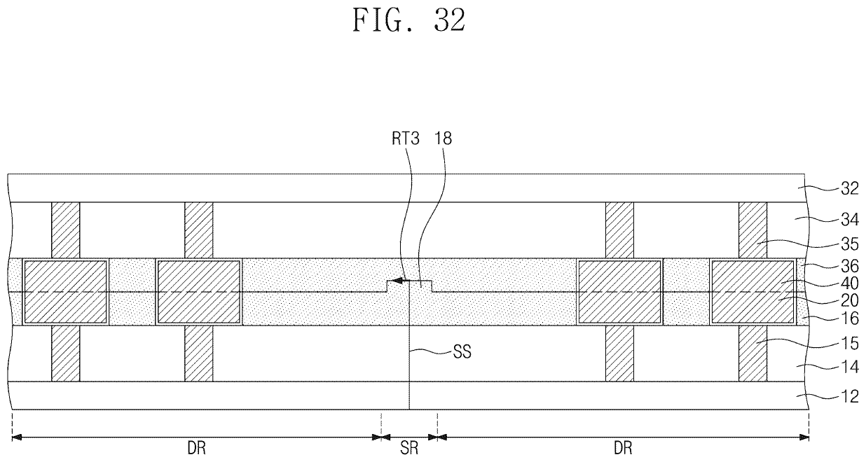

In FIG. 31, the crack may cut the first circuit layer 14, the first insulating layer 16, and the protruding portion 18 of the first insulating layer 16, and as a result, a severance section SS corresponding to the first propagation path RT1 may be formed.

However, the crack may continue to propagate. For example, the crack may propagate along a second propagation path RT2 depicted by the arrow of FIG. 31. The second propagation path RT2 may be a path that is extended from the top surface of the protruding portion 18 (e.g., from an end of the severance section SS) to a top surface of the second substrate 32 through the second insulating layer 36, the second circuit layer 34, and the second substrate 32 in a vertical direction. The second propagation path RT2 may be vertically aligned to the first propagation path RT1. For example, the first propagation path RT1 and the second propagation path RT2 may be portions of a substantially straight line or a substantially flat plane that is parallel to a vertical direction (e.g., normal to the top surface of the first substrate 12). The propagation of the crack may be achieved in a natural manner or may be caused by applying a stress on the second substrate 32 or the entire structure of FIG. 31.

The first substrate 12, the first circuit layer 14, the first insulating layer 16, the second insulating layer 36, the second circuit layer 34, and the second substrate 32 may be cut, as a result of the vertical propagation of the crack passing through them. Accordingly, the semiconductor packages, which are located on the device regions DR, respectively, may be separated from each other. For example, the semiconductor package may have a structure, in which side surfaces of the first and second insulating layers 16 and 36 are coplanar with each other, as described with reference to FIG. 1.

Alternatively, the semiconductor package may be provided in such a way that the side surface of the first insulating layer 16 is not coplanar with the side surface of the second insulating layer 36.

In FIG. 32, the crack in the resulting structure of FIG. 30 may propagate from an end of the severance section SS along an interface between the first and second insulating layers 16 and 36. For example, the crack may propagate along a third propagation path RT3 depicted by the arrow of FIG. 32. The third propagation path RT3 may be parallel to the top surface of the protruding portion 18.

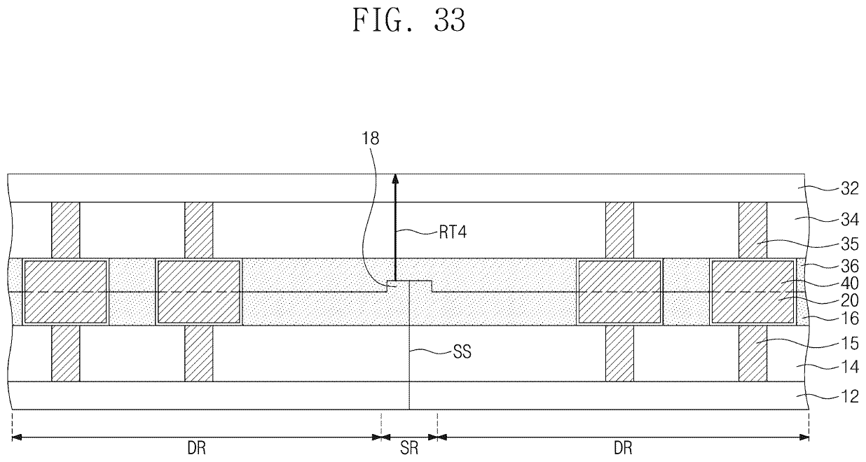

In FIG. 33, the crack may continue to propagate. For example, the crack may propagate along a fourth propagation path RT4 depicted by the arrow of FIG. 33. The fourth propagation path RT4 may be a path that is extended from the top surface of the protruding portion 18 to the top surface of the second substrate 32 through the second insulating layer 36, the second circuit layer 34, and the second substrate 32 in a vertical direction. The crack may propagate along the third propagation path RT3, which is the horizontal path, between the propagation along the first propagation path RT1 and the propagation along the fourth propagation path RT4. Thus, the fourth propagation path RT4 may be horizontally shifted from the first propagation path RT1.

The first substrate 12, the first circuit layer 14, the first insulating layer 16, the second insulating layer 36, the second circuit layer 34, and the second substrate 32 may be cut, as a result of the vertical propagation of the crack passing through them. Accordingly, the semiconductor packages, which are located on the device regions DR, respectively, may be separated from each other. For example, for the semiconductor package located on the left device region DR of FIG. 33, the first insulating layer 16 and the protruding portion 18 may have a protruding shape outward from the side surface of the second insulating layer 36, as described with reference to FIG. 6 or 8.

Alternatively, the semiconductor package may be provided in such a way that the side surface of the first insulating layer 16 is not coplanar with the side surface of the second insulating layer 36.

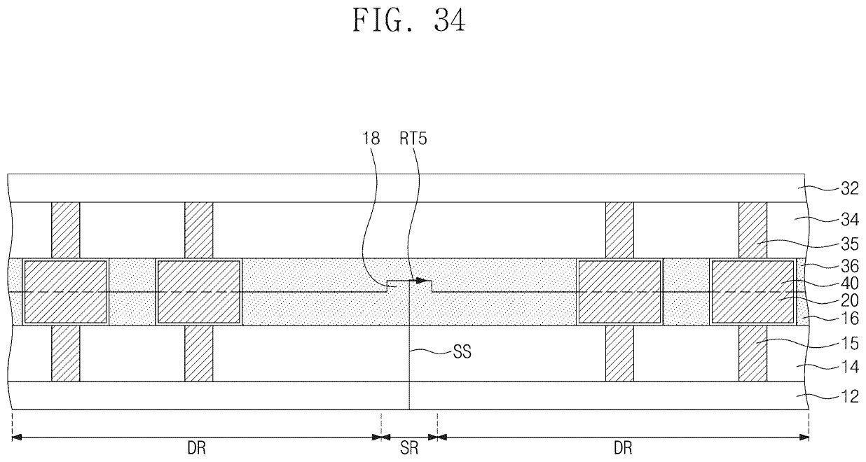

In FIG. 34, the crack in the resulting structure of FIG. 30 may propagate along the interface between the first and second insulating layers 16 and 36. For example, the crack may propagate along a fifth propagation path RT5 depicted by the arrow of FIG. 34. The fifth propagation path RT5 may be parallel to the top surface of the protruding portion 18. Here, a direction of the fifth propagation path RT5 may be antiparallel to the third propagation path RT3.

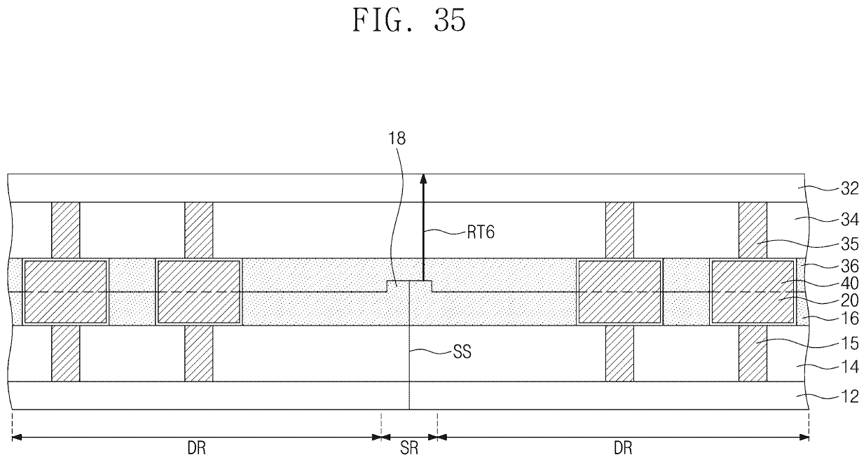

In FIG. 35, the crack may continue to propagate. For example, the crack may propagate along a sixth propagation path RT6 depicted by the arrow of FIG. 35. The sixth propagation path RT6 may be a path that is extended from the top surface of the protruding portion 18 to the top surface of the second substrate 32 through the second insulating layer 36, the second circuit layer 34, and the second substrate 32 in a vertical direction. The crack may propagate along the fifth propagation path RT5, which is the horizontal path, between the propagation along the first propagation path RT1 and the propagation along the sixth propagation path RT6. Thus, the sixth propagation path RT6 may be horizontally shifted from the first propagation path RT1.

The first substrate 12, the first circuit layer 14, the first insulating layer 16, the second insulating layer 36, the second circuit layer 34, and the second substrate 32 may be cut, as a result of the vertical propagation of the crack passing through them. Accordingly, the semiconductor packages, which are located on the device regions DR, respectively, may be separated from each other. For example, for the semiconductor package located on the left device region DR of FIG. 35, the second insulating layer 36 may include a portion protruding outward from the side surface of the first insulating layer 16, as described with reference to FIG. 10.

According to some implementations, at an interface of layers (e.g., at an interface between the first and second insulating layers 16 and 36), the crack may propagate along the interface or in a horizontal direction (e.g., along the third or fifth propagation path RT3 or RT5). However, since the crack propagates the third or fifth propagation path RT3 or RT5 that is parallel to the top surface of the protruding portion 18, the horizontal crack propagation may be confined to the top surface of the protruding portion 18. That is, the crack may not propagate a region outside the protruding portion 18. Accordingly, it is possible to prevent the crack from excessively propagating in a horizontal direction and thereby to prevent the first and second insulating layers 16 and 36 from being detached from each other. As a result, it may be possible to prevent a process failure (e.g., an incomplete cutting issue of the second insulating layer 36, the second circuit layer 34, and the second substrate 32), which may occur when the crack propagates in only the horizontal direction not in a vertical direction. For example, it may be possible to reduce a failure rate in a process of fabricating a semiconductor package and to improve structural stability of the semiconductor package.

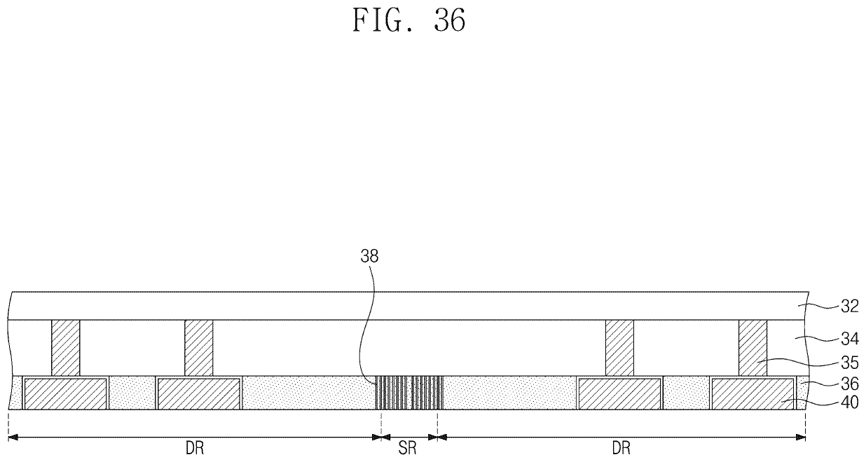

FIGS. 36 to 39 are sectional views illustrating an example of a method of fabricating a semiconductor package according to some implementations. In FIG. 36, the slit structures 38 may be formed in the second insulating layer 36 of the resulting structure of FIG. 27. For example, a plurality of holes, which vertically penetrate the second insulating layer 36, may be formed by patterning the second insulating layer 36. The slit structures 38 may be formed by filling the holes with an insulating material, or the holes themselves may be used as the slit structures 38. The slit structures 38 may be located on the scribe lane region SR.

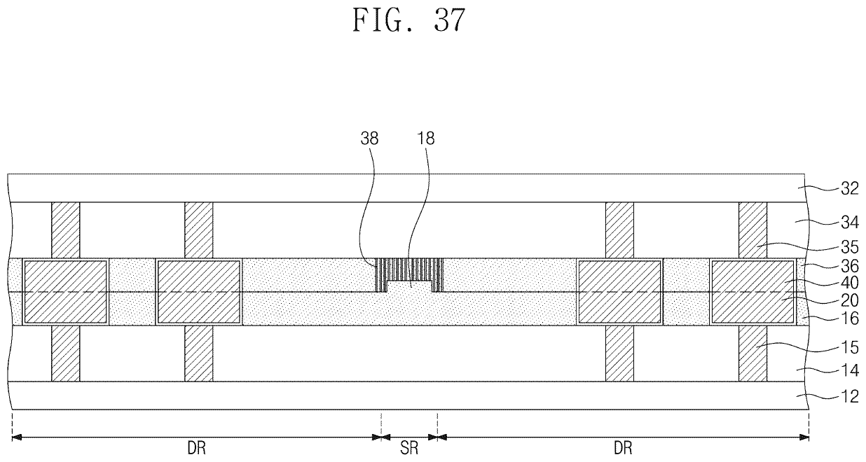

In FIG. 37, the process described with reference to FIGS. 28 and 29 may be performed. For example, the second substrate 32 may be placed on the first substrate 12 such that the first and second insulating layers 16 and 36 are in contact with each other and the first and second pads 20 and 40 are ion contact with each other. Here, the protruding portion 18 may be inserted into the second insulating layer 36. At least one of the slit structures 38 may be in contact with the top surface of the protruding portion 18. Others of the slit structures 38 may be in contact with the top surface of the first insulating layer 16. Next, a thermal treatment process may be performed to bond the first and second pads 20 and 40 to each other.

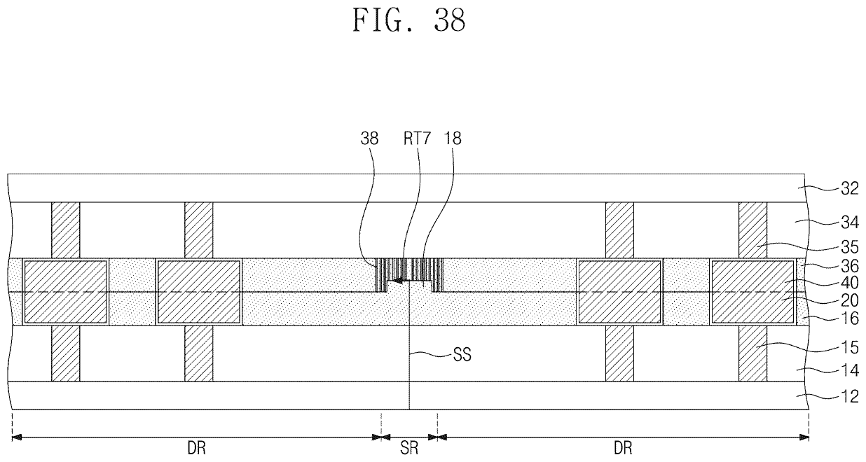

In FIG. 38, a crack may be formed in the first substrate 12. The crack may be formed on the scribe lane region SR. The crack in the first substrate 12 may propagate in a specific. The crack may propagate from an inner portion of the first substrate 12 to the top surface of the protruding portion 18 through the first circuit layer 14, the first insulating layer 16, and the protruding portion 18 of the first insulating layer 16 in a vertical direction. As a result of the propagation of the crack, the severance section SS may be formed to cut the first circuit layer 14, the first insulating layer 16, and the protruding portion 18 of the first insulating layer 16.

The crack may propagate from an end of the severance section SS along the interface between the first and second insulating layers 16 and 36. For example, the crack may propagate along a seventh propagation path RT7 depicted by the arrow of FIG. 38. The seventh propagation path RT7 may be parallel to the top surface of the protruding portion 18. A terminal point of the seventh propagation path RT7 may be in contact with one of the slit structures 38. Accordingly, the propagation of the crack along the top surface of the protruding portion 18 may be allowed, until it reaches one of the slit structures 38.

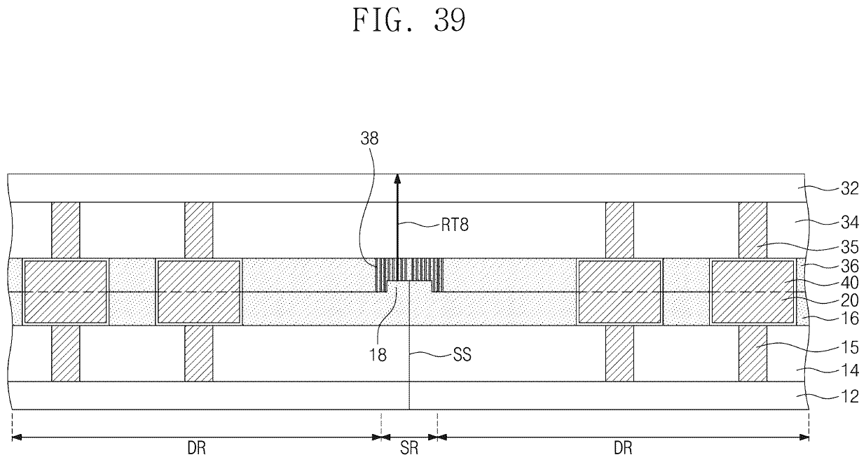

In FIG. 39, the crack may continue to propagate. For example, the crack may propagate along an eighth propagation path RT8 depicted by the arrow of FIG. 39. The slit structures 38 may be used to confine the propagation direction of the crack. The slit structures 38 may alter the propagation direction of the crack from the horizontal direction (e.g., along the seventh propagation path RT7) to the vertical direction. For example, the slit structures 38 may serve as a guide, allowing for the vertical propagation of the crack. The eighth propagation path RT8 may be a path that is extended from the top surface of the protruding portion 18 to the top surface of the second substrate 32 through the second insulating layer 36, the second circuit layer 34, and the second substrate 32 in a vertical direction. The eighth propagation path RT8 may be overlapped with one of the slit structures 38. For example, the crack may pass through one of the slit structures 38. The crack may propagate along the seventh propagation path RT7, which is the horizontal path, between the propagation along the first propagation path RT1 and the propagation along the eighth propagation path RT8. Accordingly, the eighth propagation path RT8 may be horizontally shifted from the first propagation path RT1.

The first substrate 12, the first circuit layer 14, the first insulating layer 16, the second insulating layer 36, the second circuit layer 34, and the second substrate 32 may be cut, as a result of the vertical propagation of the crack passing through them. Accordingly, the semiconductor packages, which are located on the device regions DR, respectively, may be separated from each other. For example, the semiconductor package may be fabricated to have a structure with the slit structure 38, as described with reference to FIG. 14.

According to some implementations, a semiconductor package may include a protruding portion that is provided in a first insulating layer of a lower structure, and it may be possible to prevent a process failure (e.g., a detachment issue of a second insulating layer from the first insulating layer), which may be caused by a horizontal crack propagation in a singulation process that is performed as a part of a fabrication process of the semiconductor package. Accordingly, the first and second insulating layers may be robustly bonded to each other, and the lower structure may be robustly bonded to an upper structure. As a result, it may be possible to realize a semiconductor package with improved structural stability.

In a method of fabricating a semiconductor package according to some implementations, the crack may propagate in a horizontal direction along an interface between the first and second insulating layers. The protruding portion may suppress the horizontal propagation of the crack. Accordingly, it may be possible to prevent the crack from excessively propagating in a horizontal direction and thereby to prevent the first and insulating layers from being detached from each other. As a result, it may be possible to prevent a process failure (e.g., an incomplete cutting issue of a second insulating layer, a second circuit layer, or a second substrate), which may occur when the crack propagates in only a horizontal direction without a vertical propagation. In other words, it may be possible to reduce a failure rate in a process of fabricating a semiconductor package and to improve structural stability of the semiconductor package.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A semiconductor package, comprising:
a lower structure; and
an upper structure on the lower structure,
wherein the lower structure comprises:
a first semiconductor substrate;
a plurality of first pads on the first semiconductor substrate; and
a first insulating layer provided on the first semiconductor substrate and enclosing the plurality of first pads,
wherein the upper structure comprises:
a second semiconductor substrate;
a plurality of second pads on the second semiconductor substrate; and
a second insulating layer provided on the second semiconductor substrate and enclosing the plurality of second pads,
wherein a side surface of the lower structure and a side surface of the upper structure define a stepwise structure adjacent to a bonding surface between the lower structure and the upper structure,
wherein the first insulating layer comprises a protruding portion that extends to a level higher than a top surface of the first insulating layer and extends into in the second insulating layer,
wherein the protruding portion contacts the side surface of the lower structure, and
wherein each first pad of the plurality of first pads and a corresponding second pad of the plurality of second pads contact each other and form a single object having a same material.

2. The semiconductor package of claim 1, wherein a width of the protruding portion ranges from 1 μm to 3 μm.

3. The semiconductor package of claim 1, wherein a height of the protruding portion ranges from 1 μm to 5 μm.

4. The semiconductor package of claim 1,
wherein the lower structure protrudes outward from the side surface of the upper structure, and
wherein at least a portion of a top surface of the protruding portion is exposed to an outside adjacent to the side surface of the upper structure.

5. The semiconductor package of claim 1,
wherein the upper structure protrudes outward from the side surface of the lower structure, and
wherein a portion of a bottom surface of the second insulating layer is exposed to an outside adjacent to a side surface of the protruding portion.

6. The semiconductor package of claim 1, wherein a side surface of the protruding portion is exposed to an outside adjacent to the side surface of the lower structure.

7. The semiconductor package of claim 1, wherein the protruding portion extends along an edge of the lower structure and has a closed loop shape, when viewed in a plan view.

8. The semiconductor package of claim 1,
wherein the protruding portion comprises a plurality of protruding portions that are spaced apart from each other in a direction from the side surface of the lower structure toward a center portion of the lower structure, and
wherein the side surface of the upper structure is placed on a top surface of one of the protruding portions.

9. The semiconductor package of claim 1,
wherein the upper structure further comprises a plurality of slit structures provided at the second insulating layer,
wherein the plurality of slit structures vertically extend through the second insulating layer and are exposed through a bottom surface of the second insulating layer, and
wherein at least one slit structure of the plurality of slit structures contacts a top surface of the protruding portion.

10. The semiconductor package of claim 9,
wherein the protruding portion comprises a first side surface that is coplanar with the side surface of the lower structure, and a second side surface facing a center portion of the lower structure, and
wherein another slit structure of the plurality of slit structures is disposed on the second side surface of the protruding portion and contacts the top surface of the first insulating layer.

11. The semiconductor package of claim 9, wherein each slit structure of the plurality of slit structures extends along an edge of the lower structure and has a closed loop shape, when viewed in a plan view.

12. (canceled)

13. The semiconductor package of claim 1, wherein the protruding portion has a section of a square shape, a rectangular shape, a trapezoidal shape, or a fan shape with an upward convex portion.

14. A semiconductor package, comprising:
a lower structure; and
an upper structure on the lower structure,
wherein the lower structure comprises:
a first semiconductor substrate;
a plurality of first pads on the first semiconductor substrate; and
a first insulating layer provided on the first semiconductor substrate and enclosing the plurality of first pads,
wherein the upper structure comprises:
a second semiconductor substrate;
a plurality of second pads on the second semiconductor substrate;
a second insulating layer provided on the second semiconductor substrate and enclosing the plurality of second pads; and
a slit structure vertically extending through the second insulating layer,
wherein the first insulating layer comprises a protruding portion that extends upward from a top surface of the first insulating layer and extends into the second insulating layer,
wherein a first side surface of the protruding portion is exposed to an outside adjacent to a side surface of the lower structure,
wherein the slit structure is exposed to an outside adjacent to a bottom surface of the second insulating layer and contacts a top surface of the protruding portion, and
wherein each first pad of the plurality of first pads and a corresponding second pad of the plurality of second pads contact each other and form a single object having a same material.

15. The semiconductor package of claim 14, wherein the side surface of the lower structure and a side surface of the upper structure form a stepwise structure adjacent to a bonding surface between the lower structure and the upper structure.

16. The semiconductor package of claim 15,
wherein the lower structure protrudes outward from the side surface of the upper structure, and
wherein at least a portion of a top surface of the protruding portion is exposed to an outside adjacent to the side surface of the upper structure.

17. The semiconductor package of claim 15,
wherein the upper structure protrudes outward from the side surface of the lower structure, and
wherein a portion of the bottom surface of the second insulating layer is exposed to an outside adjacent to a side surface of the protruding portion.

18. The semiconductor package of claim 14, wherein a width of the protruding portion ranges from 1 μm to 3 μm.

19. (canceled)

20. The semiconductor package of claim 14, wherein the protruding portion extends along an edge of the lower structure and has a closed loop shape, when viewed in a plan view.

21. (canceled)

22. The semiconductor package of claim 14,
wherein the slit structure comprises a plurality of slit structures,
wherein some slit structures of the plurality of slit structures contact the top surface of the protruding portion,
wherein the protruding portion comprises a second side surface that is opposite to the first side surface and faces a center portion of the lower structure, and
wherein other slit structures of the plurality of slit structures contact the top surface of the first insulating layer, on the second side surface of the protruding portion.

23-24. (canceled)

25. A semiconductor package, comprising:
a substrate;
a first semiconductor chip disposed on the substrate;
a chip stack including a plurality of second semiconductor chips that are vertically stacked on the substrate and are horizontally spaced apart from the first semiconductor chip; and
a mold layer provided on the substrate and enclosing the first semiconductor chip and the chip stack,
wherein each of the second semiconductor chips comprises:
a semiconductor substrate;
an upper pad disposed on a top surface of the semiconductor substrate;
an upper insulating layer provided on the top surface of the semiconductor substrate and enclosing the upper pad, the upper insulating layer comprising a protruding portion extending upward from a top surface of the upper insulating layer;
a lower pad disposed on a bottom surface of the semiconductor substrate; and
a lower insulating layer provided on the bottom surface of the semiconductor substrate and enclosing the lower pad,
wherein adjacent second semiconductor chips of the plurality of second semiconductor chips contact each other,
wherein, at contact surfaces between the plurality of second semiconductor chips, the lower pad and the upper pad contact each other and form a single object having a same material,
wherein the protruding portion extends along an edge of each of the plurality of second semiconductor chips and has a closed loop shape, when viewed in a plan view, and
wherein a width of the protruding portion ranges from 1 μm to 3 μm.

26-37. (canceled)
